(19) United States
(12) Patent Application Publication
(10) Pub. No.: US 2026/0314268 A1
(43) Pub. Date: Oct. 8, 2026

(54) METHOD FOR FABRICATING SUPERCONDUCTING QUBITS BY FOCUSED ION BEAM ANNEALING

(71) Applicant: BMSTU, MOSCOW (RU)

(72) Inventors: Ilya Anatolevich RODIONOV, Moscow (RU); Daria Andreevna MOSKALEVA, Moscow Oblast, Balashikha (RU); Elizaveta Aleksandrovna KRIVKO, Amur Oblast, Belogorsk (RU); Nikita Sergeevich SMIRNOV, Moscow (RU)

(21) Appl. No.: 19/523,178

(22) PCT Filed: Jul. 24, 2024
(86) PCT No.: PCT/RU2024/000237

§ 371 Date: Mar. 25, 2026

(30) Foreign Application Priority Data
Sep. 29, 2023 (RU) 2023125065

(51) Int. Cl. H10N 60/01; H01J 37/30

(52) U.S. Cl. CPC H10N 60/0912; H01J 37/30; H10N 60/0884; H01J 2237/31749

(57) ABSTRACT

The invention relates to the field of fabricating qubits and superconducting devices for quantum computers, and more particularly to systems based on thin-film Josephson junctions, and can be used for fine tuning, after fabrication, the resonance frequency of superconducting qubits containing thin-film Josephson junctions, for example adjustable-frequency or fixed-frequency qubits, as well as cryogenic Josephson parametric amplifiers. The essence of the invention is that in a method for fabricating superconducting qubits with focused ion beam annealing, which includes fabricating thin-film aluminium/aluminium-oxide/aluminium Josephson junctions (2) on a substrate (8), which are connected to two plates of a capacitor (3), and treating the superconducting qubits (1) by annealing the thin-film aluminium/aluminium-oxide/aluminium Josephson junctions (2), the superconducting qubits (1) are annealed with a Gaussian focused ion beam (13) by local changes in the properties of the thin-film aluminium/aluminium-oxide/aluminium Josephson junctions (2). The technical results of the invention consist in increasing the reproducibility of the resonance frequency tuning of any type of superconducting qubit and reducing the labour intensity and cost of the route for the fabrication of superconducting qubits and superconducting devices for quantum computers.

The proposed invention relates to the fabricating of superconducting qubits and superconducting devices for quantum computers, particularly to systems based on thin-film Josephson junctions, and can be used for precise tuning of the resonance frequency of superconducting qubits comprised of thin-film Josephson junctions after they are fabricated, such as, for example, frequency-tunable or fixed-frequency superconducting qubits, as well as cryogenic Josephson parametric amplifiers.

There is a method for annealing superconducting qubits that involves positioning an irradiating antenna directly above the first and second thin-film Josephson junctions comprising a superconducting qubit, exposing the thin-film Josephson junction to a thermal impact from an electromagnetic wave emanating from the irradiating antenna, and then moving the antenna to the next thin-film Josephson junction, which is known from patent U.S. Pat. No. 11,050,009 B2, made public on Jun. 29, 2021.

Its drawbacks include the fact that that in order to anneal a superconducting qubit, it is necessary to use additional equipment containing irradiating antennas. Due to the fixed size of the equipment, each new topology of a superconducting qubit would require to manufacture new equipment, which imposes restrictions on the flexibility of the fabricating process of superconducting qubits and also results in an increased cost.

There is also a method for annealing superconducting qubits that involves forming a plurality of superconducting qubits on a chip, determining the initial frequency for each superconducting qubit, and annealing Josephson junctions comprising said superconducting qubits, which is known from patent US 2019/0165244 A1 , made public on May 30, 2019.

Its drawbacks include the fact that, due to the large contact spot, it is impossible to place superconducting qubits on the chip in close proximity to each other, which imposes limitations on the scalability of superconducting qubit circuits. Another drawback is the low discreteness of the energy values used in the annealing of superconducting qubits, which makes it impossible to tune the resonance frequency of superconducting qubits within a wide range.

There is also a method for laser thermal annealing of superconducting qubits by treating thin-film Josephson junctions with a laser with a 532 nm-long wavelength that involves fabricating thin-film Al/AlOx/Al Josephson junctions on a substrate connected to two capacitor pads, and annealing the thin-film Al/AlOx/Al Josephson junctions with a laser generating a Gaussian-shaped beam with a diameter of 20 μm, which is known from patent U.S. Pat. No. 10,424,713 B2, made public on Sep. 24, 2019. This method can be considered the closest prior art to the proposed solution.

Its drawbacks include the fact that, during laser annealing of superconducting qubits by treating thin-film Josephson junctions, the laser Gaussian beam has a contact spot comparable to the size of the superconducting qubit, which makes it impossible to treat thin-film Josephson junctions without affecting the substrate. This results in a low reproducibility of tuning the resonance frequency of superconducting qubits. Another drawback is that laser annealing of thin-film Josephson junctions is suitable only for sparsely spaced thin-film Josephson junctions, because the temperature gradient caused by the large contact spot makes it impossible to treat closely spaced thin-film Josephson junctions with the same energy. Therefore, said method does not allow for tuning the resonance frequency of frequency-tunable superconducting qubits, being suitable only for fixed-frequency superconducting qubits. This results in stricter requirements for the fabricating of superconducting qubits, a longer pipeline due to the need for additional cleaning stages and, eventually, an increased cost of the fabricating process.

The objective of the invention is to increase the reproducibility of tuning the resonance frequency of superconducting qubits of any type, to reduce the labor-intensiveness and cost of the pipeline for fabricating superconducting qubits and superconducting devices for quantum computers.

The objective of the proposed invention is achieved by a method for fabricating superconducting qubits with focused ion beam annealing that involves fabricating thin-film Al/AlOx/Al Josephson junctions on a substrate, which are connected to two capacitor pads, and treating superconducting qubits by annealing thin-film Al/AlOx/Al Josephson junctions, wherein annealing is carried out by a Gaussian-shaped focused ion beam by locally changing the properties of thin-film Al/AlOx/Al Josephson junctions.

According to an exemplary embodiment, the capacitor pads are made of either aluminum, or niobium, or tantalum, or molybdenum.

According to an exemplary embodiment, the Gaussian-shaped focused ion beam is formed by either helium ions, or neon ions, or gallium ions, or gold ions, or silicon ions.

According to an exemplary embodiment, the treatment of superconducting qubits by annealing thin-film Al/AlOx/Al Josephson junctions with a focused ion beam is carried out by a Gaussian-shaped focused ion beam with a diameter of 0.3 to 30 nm.

According to an exemplary embodiment, superconducting qubits are treated by annealing thin-film Al/AlOx/Al Josephson junctions with a focused ion beam by sequentially locally changing the properties of thin-film Al/AlOx/Al Josephson junctions with a focused beam.

According to an exemplary embodiment, when treating superconducting qubits by annealing thin-film Al/AlOx/Al Josephson junctions with a focused ion beam, the penetration depth of charged particles in the volume of thin-film Al/AlOx/Al Josephson junctions is adjusted by changing the irradiation dose within the range from 1×10¹¹ to 5×10¹⁴ ion/cm².

According to an exemplary embodiment, when treating superconducting qubits by annealing thin-film Al/AlOx/Al Josephson junctions with a focused ion beam, the beam is applied directly to the region of thin-film Al/AlOx/Al Josephson junctions without heating the substrate.

According to an exemplary embodiment, when treating superconducting qubits by annealing thin-film Al/AlOx/Al Josephson junctions with a focused ion beam, the beam is applied to both the region of thin-film Al/AlOx/Al Josephson junctions and the substrate.

According to an exemplary embodiment, when treating superconducting qubits by annealing thin-film Al/AlOx/Al Josephson junctions with a focused ion beam, the area of the treated region exactly corresponds to the area of the thin-film Al/AlOx/Al Josephson junctions.

According to an exemplary embodiment, when treating superconducting qubits by annealing thin-film Al/AlOx/Al Josephson junctions with a focused ion beam, the specified area of the treated region is larger than the area of the thin-film Al/AlOx/Al Josephson junctions.

According to an exemplary embodiment, when treating superconducting qubits by annealing thin-film Al/AlOx/Al Josephson junctions with a focused ion beam, the shape of the treated region of the thin-film Al/AlOx/Al Josephson junctions is specified by means of polygons, both simple and complex shapes.

According to an exemplary embodiment, when treating superconducting qubits by annealing thin-film Al/AlOx/Al Josephson junctions with a focused ion beam, the energy of charged particles applied to the thin-film Al/AlOx/Al Josephson junctions is specified for each treated region.

According to an exemplary embodiment, when treating superconducting qubits, both fixed-frequency and frequency-tunable, each thin-film Al/AlOx/Al Josephson junction in the superconducting qubit is treated independently, without cross-influence from neighboring thin-film Al/AlOx/Al Josephson junctions.

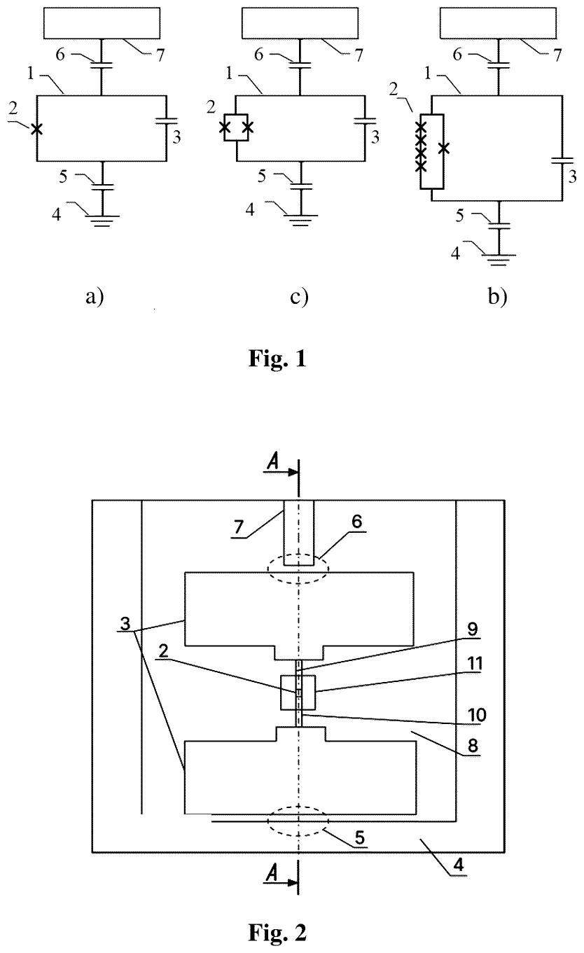

FIG. 1 illustrates electrical circuits of (a) a fixed-frequency superconducting qubit, (b) a frequency-tunable superconducting qubit, and (c) a fluxonium qubit. According to the preferred embodiments, superconducting qubits are comprised of one or more thin-film Josephson junctions and a parallel-connected capacitor. The Josephson junction and the capacitor can be capacitively coupled to both the readout line and the ground plane.

FIG. 2 illustrates the topology of a thin-film Al/AlOx/Al Josephson junction connected to two capacitor pads and to a grounding plane. According to the preferred embodiment, the treated region is larger than the area of the Josephson junction. However, alternatively, the area of the treated region can be exactly the same as that of the Josephson junction.

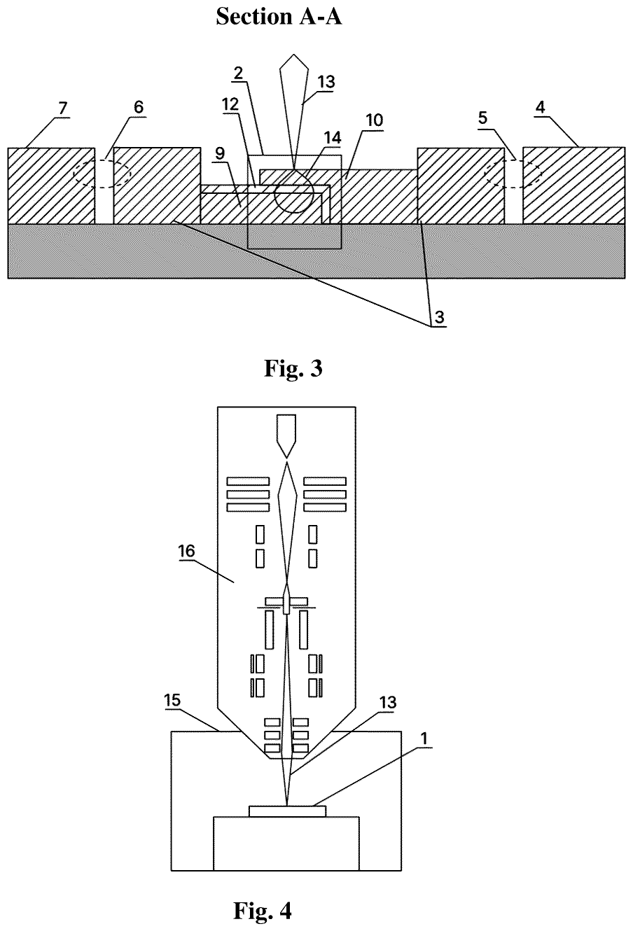

FIG. 3 shows a cross-section of a thin-film Al/AlOx/Al Josephson junction when it is being treated with a Gaussian-shaped focused ion beam. It should be noted that the size of the contact spot is much smaller than the feature size of the thin-film Josephson junction. According to the preferred embodiment, the penetration depth of charged particles is greater than the thickness of the metal of the upper electrode and the tunnel barrier. However, alternatively, the penetration depth of charged particles can be less than or exactly the same as the thickness of the metal of the upper electrode and the tunnel barrier.

FIG. 4 illustrates a simplified diagram of a scanning helium ion microscope used for ion annealing of superconducting qubits, which can produce a focused ion beam with a diameter of less than 30 nm.

The method for fabricating superconducting qubits (see FIG. 1) involving annealing with a focused ion beam can be implemented by a number of known technological processes. Two examples include 1) a subtractive process for fabricating superconducting qubits based on three-layer thin-film Josephson junctions and 2) a Dolan bridge-based process. Below, the fabricating process of a superconducting qubit using the Dolan bridge-based process is described as an example.

On the plate 8 (see FIG. 2, FIG. 3), superconducting qubits 1 are formed from silicon, or sapphire, or magnesium oxide with a diameter between 25 mm and 300 mm and a thickness between 430 μm and 650 μm using electron beam lithography and shadow evaporation on thin-film Al/AlOx/Al or Nb—Al₂O₃—Nb Josephson junctions 2, wherein the lower thin-film electrode 9 is 15-25 nm thick, the upper thin-film electrode 10 is 35-60 nm thick, and the aluminum oxide tunnel barrier 12 is 0.1-10 nm thick. In such processes, a thin-film Josephson junction 2 is positioned between the capacitor pads 3, which can be capacitively coupled to a line 7 through a capacitor 6 or to a grounding plane 4 through a capacitor 5. The layout and geometry of the superconducting qubit 1 are selected based on modeling and design data. According to an exemplary embodiment, the capacitance of the capacitor 3 is within the range from 0.1 fF to 200 fF. According to an exemplary embodiment of superconducting qubit 1, the critical current of thin-film Josephson junctions 2 is within the range from 10 nA to 100 nA. The critical current is related to the room-temperature resistance of the thin-film Josephson junction 2 through the Ambegaokar-Baratoff relation. In particular, said relation predicts that the resistance of the thin-film Josephson junction 2 before transitioning to the superconducting state is inversely proportional to the critical current after transitioning to the superconducting state. Below, the fabricating process of a transmon qubit is described as an example.

According to an exemplary embodiment of superconducting qubit 1, a two-layer resistive mask is formed on the surface of the substrate 8, the lower layer of which can be made of a methyl methacrylate (MMA) copolymer, and the upper, thinner layer can be made of polymethyl methacrylate (PMMA). Next, electron beam lithography is performed to form the geometry of thin-film Josephson junctions 2 in the two-layer resistive mask. Then, the regions of the resistive mask exposed to the electron beam are removed in a solution of methyl isobutyl ketone: isopropyl alcohol (MIBK:IPA) at a concentration of 1:3. The MMA layer is more sensitive to the electron beam, which makes it possible to form a suspended bridge made of PMMA, also called the Dolan bridge. Next, the sample is placed in an electron beam evaporation unit, where aluminum is evaporated at two different angles through previously formed holes in the resistive mask, with intermediate oxidation in an argon atmosphere between the stages of aluminum evaporation. After evaporation, a thin-film Josephson junction 2 is formed in the area of the Dolan suspended bridge (see FIG. 3). Then, the remaining resist material and unwanted metal are removed by placing the sample in N-methyl-2-pyrrolidone (NMP). This basic fabricating process can be used with other additional fabricating steps, such as plasma-enhanced chemical vapor deposition (PECVD), photolithography, as well as plasma and wet etching, to manufacture more complex devices. Next, superconducting qubits 1 are annealed with a Gaussian-shaped focused ion beam 13 by locally changing the properties of thin-film Josephson junctions 2 (see FIG. 3) in the chamber 15 of a scanning helium ion microscope 16 (see FIG. 4).

According to an exemplary embodiment, the capacitor pads 3 are made of either aluminum, or niobium, or tantalum, or molybdenum, with a film thickness from 80 nm to 130 nm and feature sizes of capacitor pads 3 from 1 μm to 500 μm.

According to an exemplary embodiment, the Gaussian-shaped focused ion beam 13 is formed by either helium ions, or neon ions, or gallium ions, or gold ions, or silicon ions, with a focused ion beam 13 energy from 10 keV to 30 keV.

According to an exemplary embodiment, the treating of superconducting qubits 1 by annealing thin-film Al/AlOx/Al Josephson junctions 2 with a focused ion beam is carried out by a Gaussian-shaped focused ion beam 13 with a diameter of 0.3 to 30 nm, wherein the diameter of the Gaussian-shaped focused ion beam 13 is adjusted by varying the diameter of the aperture installed in the electron optical column of the scanning helium ion microscope 16.

Thin-film Al/AlOx/Al Josephson junctions 2, for example, can be treated with focused He⁺ and Ne⁺ beams 13 with a beam energy between 10 keV and 30 keV and a beam diameter between 3 nm and 15 nm. A change in the diameter of the focused ion beam 13 may be indicated by a change in the current of the focused ion beam for a given aperture of the scanning helium ion microscope 16. For example, an aperture diameter of 70 μm corresponds to a focused ion beam current of 1.5 pA and a beam diameter of 15 nm, and an aperture diameter of 5 μm corresponds to a beam current of 0.2 pA and a beam diameter of 3 nm. The region treated by the focused ion beam 11 can be specified by compiling the treatment topology in electronic format. The area of the treated region 11, for example, for each thin-film Al/AlOx/Al Josephson junction 2 can be equal to 5×5 μm, wherein the focused ion beam 13 will affect both the Josephson junction area 2 and the silicon substrate 8.

When treating thin-film Josephson junctions 2 with high-energy focused ion beams 13, an increase in the room-temperature resistance (R_{N}) of Josephson junctions 2 may be observed, which may be caused by a local change in the structure of a thin-film Josephson junction 2 due to being heated by the focused ion beam 13. The scattering range of R N values can be reduced by reducing the diameter (current) of the focused ion beam 13. For instance, for a focused ion beam 13 with a diameter of 8 nm (current: 0.6 pA), the scattering range of R_{N} values can correspond to 8.3%, and for a beam with a diameter of 3 nm (current: 0.2 pA) it can correspond to 3.5%. Also, the scattering range can be reduced by reducing the energy of the focused ion beam, which can be explained by reducing the degree of damage to the substrate due to a reduced number of back-reflected ions. For a beam with an energy of 30 keV, the scattering range can be 15%, and for a beam with an energy of 10 keV it can be 10%. Depending on the embodiment, the energy, as well as the diameter of the focused ion beam, the room-temperature resistance shift values can be tested and determined for a given set of conditions with high processing accuracy.

According to an exemplary embodiment, superconducting qubits 1 are treated by annealing thin-film Al/AlOx/Al Josephson junctions 2 with a focused ion beam 13 by sequentially locally changing the properties of thin-film Al/AlOx/Al Josephson junctions 2 with a focused beam 13, for example, by sequentially locally heating the structure of thin-film Al/AlOx/Al Josephson junctions 2 with phonons formed as a result of inelastic collisions between ions of the primary beam and atoms of the structure of the thin-film Josephson junction, or by sequentially forming vacancies in the structure of the tunnel barrier of the Josephson junction from Al2O3 12.

According to an exemplary embodiment, when treating superconducting qubits 1 by annealing thin-film Al/AlOx/Al Josephson junctions 2 with a focused ion beam 13, the penetration depth of charged particles 14 in the volume of thin-film Al/AlOx/Al Josephson junctions 2 within the range from 20 nm to 70 nm is adjusted by changing the irradiation dose within the range from 1×10¹¹ ion/cm² to 5×10¹⁴ ion/cm² while increasing the scanning time per point within the range from 0.5 μs to 50 μs and changing the scanning step within the range from 20 nm to 0.5 nm.

Thin-film Al/AlOx/Al Josephson junctions 2 can be treated, for example, with focused He⁺ and Ne⁺ beams 13 with irradiation doses varying within the range from 1×10¹¹ ion/cm² to 5×10¹⁴ ion/cm² given the fixed area of the treated region 11. The region treated by the focused ion beam 11 can be specified by compiling the treatment topology in electronic format. The area of the treated region 11 for each thin-film Al/AlOx/Al Josephson junction 2 can be exactly the same as the area thereof. For example, thin-film Josephson junctions 2 can be treated in the chamber 15 of an OrionNanoFab scanning helium ion microscope 16 with a beam energy of 10 keV and an ion beam current of 0.2 pA. However, other ion optical systems with different focused ion beam parameters can be used to achieve optimal frequency shift parameters for superconducting qubits.

When the irradiation dose of the focused ion beam is changed, for example, within the range from 0.02×10¹³ ion/cm² to 7.90×10¹³ ion/cm², it is possible to smoothly increase the room-temperature resistance of thin-film Al/AlOx/Al Josephson junctions 2 within the range from 1% to 40% for a focused Ne⁺ beam, or within the range from 1% to 25% for a focused He⁺ beam 13. For example, when treating thin-film Al/AlOx/Al Josephson junctions 2 with a focused ion beam 13 with an irradiation dose of less than 4×10¹³ ion/cm2, it is possible to controllably change the resonance frequency of superconducting qubits 1 within the range from 50 MHz to 100 MHz, and at an irradiation dose of more than 4×10¹³ ion/cm², the resonance frequency of superconducting qubits 1 can change within the range from 100 MHz to 400 MHz.

According to an exemplary embodiment, when treating superconducting qubits 1 by annealing thin-film Al/AlOx/Al Josephson junctions 2 with a focused ion beam 13, the beam 13 is applied directly to the region of thin-film Al/AlOx/Al Josephson junctions 2 without heating the substrate 8.

According to an exemplary embodiment, when treating superconducting qubits 1 by annealing thin-film Al/AlOx/Al Josephson junctions 2 with a focused ion beam 13, the beam 13 is applied to both the region of thin-film Al/AlOx/Al Josephson junctions 2 and the substrate 8.

According to an exemplary embodiment, when treating superconducting qubits 1 by annealing thin-film Al/AlOx/Al Josephson junctions 2 with a focused ion beam 13, the area of the treated region 11 exactly corresponds to the area of the thin-film Al/AlOx/Al Josephson junctions 2 and ranges from 0.01 μm² to 1 μm².

According to an exemplary embodiment, when treating superconducting qubits 1 by annealing thin-film Al/AlOx/Al Josephson junctions 2 with a focused ion beam 13, the specified area of the treated region 11 is larger than the area of the thin-film Al/AlOx/Al Josephson junctions 2, ranging from 1 μm² to 100 μm².

According to an exemplary embodiment, when treating superconducting qubits 1 by annealing thin-film Al/AlOx/Al Josephson junctions 2 with a focused ion beam 13, the shape of the treated region 11 of the thin-film Al/AlOx/Al Josephson junctions 2 is specified by means of polygons, both simple and complex shapes, such as, for example, rectangles, circles, ellipses, or polygons whose shapes exactly follow the shape of the thin-film Al/AlOx/Al Josephson junctions 2.

According to an exemplary embodiment, when treating superconducting qubits 1 by annealing thin-film Al/AlOx/Al Josephson junctions 2 with a focused ion beam 13, the energy of charged particles applied to the thin-film Al/AlOx/Al Josephson junctions 2 is specified for each treated region 11 within the range from 1×10¹¹ ion/cm² to 5×10¹⁴ ion/cm² by forming a polygon in the area of each thin-film Al/AlOx/Al Josephson junction 2.

According to an exemplary embodiment, when treating superconducting qubits 1, both fixed-frequency and frequency-tunable, each thin-film Al/AlOx/Al Josephson junction 2 in the superconducting qubit 1 is treated independently, without cross-influence from neighboring thin-film Al/AlOx/Al Josephson junctions 2, by setting the treated region 11 and the energy of charged particles for each thin-film Al/AlOx/Al Josephson junction 2.

For example, transmon qubits, both fixed-frequency and frequency-tunable, can be treated with a focused Ne⁺ beam with an energy of 10 keV and a beam current of 0.2 pA. For example, a frequency-fixed transmon qubit can be treated, with a resonance frequency of 4.2 GHz and a relaxation time of 370 μs. Such qubit can be treated with a focused ion beam and re-characterized, which would result in the resonance frequency of 4.1 GHz and the relaxation time of 340 μs. A second fixed-frequency transmon qubit with a resonance frequency of 4.52 GHz and a relaxation time of 159 μs can, for example, be treated with a greater exposure to the focused ion beam, which would result in the frequency of 4.38 GHz and the relaxation time of 320 μs. The increase in relaxation time may be due to the growing gap between the qubit's resonance frequency and the frequency of the TLS defect. Also, for example, frequency-tunable transmon qubits can be treated with a focused neon ion beam. For example, their resonance frequencies before treatment can be 4.85 and 4.66 GHz. Thin-film Josephson junctions comprising each of the frequency-tunable superconducting qubits can be treated by the focused ion beam independently, without cross-exposure. After treatment, the resulting resonance frequencies of these superconducting qubits may be equal to 4.74 GHz and 4.57 GHz. The resulting frequency of the superconducting qubit can be determined as applicable to the current quantum application, so that the superconducting qubit can be fixed at this frequency.

The fact that in the method for fabricating superconducting qubits with focused ion beam annealing that involves fabricating thin-film Al/AlOx/Al Josephson junctions 2 on a substrate 8, which are connected to two capacitor pads 3, and treating superconducting qubits 1 by annealing thin-film Al/AlOx/Al Josephson junctions 2, annealing is carried out by a Gaussian-shaped focused ion beam 13 by locally changing the properties of thin-film Al/AlOx/Al Josephson junctions 2 provides an increase in the reproducibility of tuning the resonance frequency of superconducting qubits 1 of any type and a reduction in the labor-intensiveness and cost of the pipeline for fabricating superconducting qubits 1. This is achieved by limiting the treated region 11 specifically to the area of thin-film Al/AlOx/Al Josephson junctions 2, which results in that closely located thin-film Al/AlOx/Al Josephson junctions 2 can be treated individually, both with the same and with different energy, which allows for group treatment of closely located thin-film Al/AlOx/Al Josephson junctions 2 and reduces the fabricating quality requirements for superconducting qubits 1.

The fact that the capacitor pads 3 can be made of either aluminum, or niobium, or tantalum, or molybdenum results in that ion annealing of thin-film Al/AlOx/Al Josephson junctions 2 can be carried out for any process pipeline for fabricating superconducting qubits 1, which provides an increase in the flexibility of the fabricating process of superconducting qubits 1 and, as a result, an improvement in the fabricating quality of superconducting qubits 1.

The fact that the Gaussian-shaped focused ion beam 13 is formed by either helium ions, or neon ions, or gallium ions, or gold ions, or silicon ions results in that during ion annealing of thin-film Al/AlOx/Al Josephson junctions 2, it is possible to change the diameter of the focused beam 13 within the range from 30 nm to 0.3 nm, which allows to adjust the diameter of the contact spot of the focused beam 13, as well to adjust the amorphization degree of the structure of the thin-film Al/AlOx/Al Josephson junction 2, and, as a result, provides an increase in the reproducibility of tuning the resonance frequency of superconducting qubits 1 of any type.

The fact that the treatment of superconducting qubits 1 by annealing thin-film Al/AlOx/Al Josephson junctions 2 with a focused ion beam is carried out by a Gaussian-shaped focused ion beam 13 with a diameter of 0.3 to 30 nm results in that the contact spot of the focused beam 13 during ion annealing of thin-film Al/AlOx/Al Josephson junctions 2 can be reduced up to 1 nm, which allows for targeted energy transfer from the beam 13 to the atoms of the thin-film Al/AlOx/Al Josephson junctions 2 and, as a result, provides an increase in the reproducibility of tuning the resonance frequency of superconducting qubits 1 of any type.

The fact that superconducting qubits 1 are treated by annealing thin-film Al/AlOx/Al Josephson junctions 2 with a focused ion beam 13 by sequentially locally changing the properties of thin-film Al/AlOx/Al Josephson junctions 2 with a focused beam 13 provides an increase or decrease in room-temperature resistance of thin-film Al/AlOx/Al Josephson junctions 2, which provides a decrease or increase in the resonance frequency of superconducting qubits 1 and, as a result, a decrease in the fabricating quality requirements for superconducting qubits 1.

The fact that, when treating superconducting qubits 1 by annealing thin-film Al/AlOx/Al Josephson junctions 2 with a focused ion beam 13, the penetration depth of charged particles 14 in the volume of thin-film Al/AlOx/Al Josephson junctions 2 is adjusted by changing the irradiation dose within the range from 1×10¹¹ to 5×10¹⁴ ion/cm² makes it possible to adjust the room-temperature resistance of thin-film Al/AlOx/Al Josephson junctions 2 within the range from 1% to 40%, which provides a change in the resonance frequency of superconducting qubits 1 within the range from 50 MHz to 600 MHz and, as a result, a decrease in the fabricating quality requirements for superconducting qubits 1.

The fact that, when treating superconducting qubits 1 by annealing thin-film Al/AlOx/Al Josephson junctions 2 with a focused ion beam 13, the beam 13 is applied directly to the region of thin-film Al/AlOx/Al Josephson junctions 2 without heating the substrate 8 results in that ion annealing does not cause any change in the structure of the substrate 8, which minimizes defects in the substrate 8—capacitor 3 interface and, as a result, provides an improvement in the fabricating quality of superconducting qubits 1.

The fact that, when treating superconducting qubits 1 by annealing thin-film Al/AlOx/Al Josephson junctions 2 with a focused ion beam 13, the beam 13 is applied to both the region of thin-film Al/AlOx/Al Josephson junctions 2 and the substrate 8 results in that the region of thin-film Al/AlOx/Al Josephson junctions 2 is heated both directly due to interaction with the focused ion beam 13 and indirectly due to cross-heating from the substrate 8, which provides an increased thermal impact on the region with thin-film Al/AlOx/Al Josephson junctions 2 and, as a result, an expanded range of tuning the resonance frequency of superconducting qubits 1.

The fact that, when treating superconducting qubits 1 by annealing thin-film Al/AlOx/Al Josephson junctions 2 with a focused ion beam 13, the area of the treated region 11 exactly corresponds to the area of the thin-film Al/AlOx/Al Josephson junctions 2 results in that ion annealing of each of the thin-film Al/AlOx/Al Josephson junctions 2 can be carried out separately, with individually set parameters, which makes possible, by means of ion annealing, to eliminate the non-reproducibility of the electrical parameters of thin-film Al/AlOx/Al Josephson junctions 2 comprising a frequency-tunable superconducting qubit 1, and, as a result, provides a decrease in the fabricating quality requirements for superconducting qubits 1.

The fact that, when treating superconducting qubits 1 by annealing thin-film Al/AlOx/Al Josephson junctions 2 with a focused ion beam 13, the specified area of the treated region 11 is larger than the area of the thin-film Al/AlOx/Al Josephson junctions 2 results in that the thin-film Al/AlOx/Al Josephson junctions 2 comprising a frequency-tunable superconducting qubit 1 can be treated together with the same energy of the focused beam 13, which minimizes positioning errors when moving between adjacent thin-film Al/AlOx/Al Josephson junctions 2 and, as a result, provides an increase in the accuracy of tuning the resonance frequency of superconducting qubits 1 of any type.

The fact that, when treating superconducting qubits 1 by annealing thin-film Al/AlOx/Al Josephson junctions 2 with a focused ion beam 13, the shape of the treated region 11 of the thin-film Al/AlOx/Al Josephson junctions 2 is specified by means of polygons, both simple and complex shapes, provides a limited area of interaction between the focused beam 13 and the interfaces of the superconducting qubit 1, which minimizes the number of defects in the volume of thin-film Al/AlOx/Al Josephson junctions 2 caused by thermal impact, and, as a result, provides an improvement in the fabricating quality of superconducting qubits 1.

The fact that, when treating superconducting qubits 1 by annealing thin-film Al/AlOx/Al Josephson junctions 2 with a focused ion beam 13, the energy of charged particles applied to the thin-film Al/AlOx/Al Josephson junctions 2 is specified for each treated region 11 results in that, for each thin-film Al/AlOx/Al Josephson junction 2, the number of charged particles is controlled, both those reaching the tunnel barrier of the Josephson junction 12 and those slowed down in the upper thin-film aluminum electrode 10, which allows to monitor the number of vacancy-type defects occurring in the volume of thin-film Al/AlOx/Al Josephson junctions 2 during ion annealing of thin-film Al/AlOx/Al Josephson junctions 2 and, as a result, provides an improvement in the fabricating quality of superconducting qubits 1.

The fact that, when processing superconducting qubits 1, both fixed-frequency and frequency-tunable, each thin-film Al/AlOx/Al Josephson junction 2 in the superconducting qubit 1 is processed independently, without cross-influence from neighboring thin-film Al/AlOx/Al Josephson junctions 2, results in that thin-film Al/AlOx/Al Josephson junctions 2 comprising frequency-tunable superconducting qubits 1 can be processed with both the same and different energies, which makes it possible, during ion annealing, to account for the asymmetry of superconducting qubits 1 and, as a result, provides an increase in the reproducibility of tuning the resonance frequency of superconducting qubits 1 of any type.

1. A method for fabricating superconducting qubits with focused ion beam annealing that involves manufacturing thin-film Al/AlOx/Al Josephson junctions (2) on a substrate (8), which are connected to two capacitor pads (3), and treating qubits (1) by annealing thin-film Al/ AlOx/Al Josephson junctions (2), characterized in that annealing is carried out by a Gaussian-shaped focused ion beam (13) by locally changing the properties of thin-film Al/AlOx/Al Josephson junctions (2).

2. The method according to claim 1, characterized in that the capacitor pads (3) are made of either aluminum, or niobium, or tantalum, or molybdenum.

3. The method according to claim 1, characterized in that the Gaussian-shaped focused ion beam (13) is formed by either helium ions, or neon ions, or gallium ions, or gold ions, or silicon ions.

4. The method according to claim 1 characterized in that the treatment of superconducting qubits (1) by annealing thin-film Al/AlOx/Al Josephson junctions (2) with a focused ion beam is carried out by a Gaussian-shaped focused ion beam (13) with a diameter of 0.3 to 30 nm.

5. The method according to claim 1 characterized in that superconducting qubits (1) are treated by annealing thin-film Al/AlOx/Al Josephson junctions (2) with a focused ion beam (13) by sequentially locally changing the properties of thin-film Al/AlOx/Al Josephson junctions (2) with a focused beam (13).

6. The method according to claim 1 characterized in that when treating superconducting qubits (1) by annealing thin-film Al/AlOx/Al Josephson junctions

(2) with a focused ion beam (13), the penetration depth of charged particles (14) in the volume of thin-film Al/AlOx/Al Josephson junctions (2) is adjusted by changing the irradiation dose within the range from 1×10¹¹ to 5×10¹⁴ ion/cm².

7. The method according to claim 1 characterized in that when treating superconducting qubits (1) by annealing thin-film Al/AlOx/Al Josephson junctions (2) with a focused ion beam (13), the beam (13) is applied directly to the region (11) of thin-film Al/AlOx/Al Josephson junctions (2) without heating the substrate (8).

8. The method according to claim 1 characterized in that when treating superconducting qubits (1) by annealing thin-film Al/AlOx/Al Josephson junctions (2) with a focused ion beam (13), the beam (13) is applied to both the region (11) of thin-film Al/AlOx/Al Josephson junctions (2) and the substrate (8).

9. The method according to claim 7 characterized in that when treating superconducting qubits (1) by annealing thin-film Al/AlOx/Al Josephson junctions (2) with a focused ion beam (13), the area of the treated region (11) exactly corresponds to the area of the thin-film Al/AlOx/Al Josephson junctions (2).

10. The method according to claim 7 characterized in that when treating superconducting qubits (1) by annealing thin-film Al/AlOx/Al Josephson junctions (2) with a focused ion beam (13), the specified area of the treated region (11) is larger than the area of the thin-film Al/AlOx/Al Josephson junctions (2).

11. The method according to claim 7, characterized in that when treating superconducting qubits (1) by annealing thin-film Al/AlOx/Al Josephson junctions (2) with a focused ion beam (13), the shape of the treated region (11) of the thin-film Al/AlOx/Al Josephson junctions (2) is specified by means of polygons, both simple and complex shapes.

12. The method according to claim 7 characterized in that when treating superconducting qubits (1) by annealing thin-film Al/AlOx/Al Josephson junctions

(2) with a focused ion beam (13), the energy of charged particles applied to the thin-film Al/AlOx/Al Josephson junctions (2) is specified for each treated region (11).

13. The method according to claim 1, characterized in that when treating superconducting qubits (1), both fixed-frequency and frequency-tunable, each thin-film Al/AlOx/Al Josephson junction (2) in the qubit (1) is treated independently, without cross-influence from neighboring thin-film Al/AlOx/Al Josephson junctions (2).

14. The method according to claim 8, characterized in that when treating superconducting qubits (1) by annealing thin-film Al/AlOx/Al Josephson junctions (2) with a focused ion beam (13), the area of the treated region (11) exactly corresponds to the area of the thin-film Al/AlOx/Al Josephson junctions (2).

15. The method according to claim 8, characterized in that when treating superconducting qubits (1) by annealing thin-film Al/AlOx/Al Josephson junctions (2) with a focused ion beam (13), the specified area of the treated region (11) is larger than the area of the thin-film Al/AlOx/Al Josephson junctions (2).

16. The method according to claim 8, characterized in that when treating superconducting qubits (1) by annealing thin-film Al/AlOx/Al Josephson junctions (2) with a focused ion beam (13), the shape of the treated region (11) of the thin-film Al/AlOx/Al Josephson junctions (2) is specified by means of polygons, both simple and complex shapes.

17. The method according to claim 8, characterized in that when treating superconducting qubits (1) by annealing thin-film Al/AlOx/Al Josephson junctions (2) with a focused ion beam (13), the energy of charged particles applied to the thin-film Al/AlOx/Al Josephson junctions (2) is specified for each treated region (11).
